(19) United States
(12) Patent Application Publication
(10) Pub. No.: US 2007/0152714 A1
(43) Pub. Date: Jul. 5, 2007

(54) Logic circuit

(75) Inventor: Ho-Chun Wu, Luodong Township (TW)

Correspondence Address: BACON & THOMAS, PLLC, 625 SLATERS LANE, FOURTH FLOOR, ALEXANDRIA, VA, 22314, US

(73) Assignee: REALTEK SEMICONDUCTOR CORP., Hsinchu (TW)

(21) Appl. No.: 11/649,301

(22) Filed: Jan. 4, 2007

(30) Foreign Application Priority Data
Jan. 5, 2006 (TW) 095100453

(51) Int. Cl. H03K 19/094

(52) U.S. Cl. 326/113

(57) ABSTRACT

The present invention relates to a logic circuit comprising a first and a second circuits coupled in series between two voltage levels, wherein the first circuit includes a plurality of first transistors coupled in parallel and each adapted to receive an input signal; the second circuit includes a plurality of transistor sets each including a plurality of second transistors, the second transistors are coupled in series and to one of the input signals, and the second transistors of each transistor set couples to the input signals in a manner different from that of each of the remaining transistor sets. By utilizing this logic circuit, to all of the input signals, the second circuit operates with the same time delay.

### FIELD OF THE INVENTION

The present invention relates to logic circuits, and more particularly to a logic circuit contributing a low signal skew.

### BACKGROUND OF THE INVENTION

A conventional phase-locked loop (PLL) 10 is coupled to a signal input 16 and a signal output 17 as shown in FIG. 1. A reference frequency is fed to the PLL 10 from the signal input 16. The reference frequency is then processed by the PLL 10 and a signal having a specific relation with respect to the reference frequency is outputted from the signal output 17.

Referring to FIG. 1 again, the PLL 10 is implemented as a charge pump (CP) based PLL 10. The CP based PLL 10 comprises a phase/frequency detector (PFD) 11, a CP 12, a filter 13, a voltage control oscillator (VCO) 14, and a feedback module (e.g., frequency divider) 15. The phase/frequency detector 11 is adapted to output a logic level (U/D) signal based on the reference frequency sent from the signal input 16 and a feedback signal sent from the feedback module 15. The CP 12 is adapted to convert the logic level (U/D) signal into a current signal (Ip). The filter 13 is adapted to further convert the current signal (Ip) generated by the CP 12 into an analog voltage signal (VC). The VCO 14 is adapted to generate an output signal in response to the analog VC. Frequency of the output signal is controlled by the analog VC. The feedback module 15 is adapted to cause frequency and phase of the signal from the signal output 17 to correspond to frequency and phase of the reference frequency sent from the signal input 16.

Referring to FIG. 2 in conjunction with FIG. 1, the phase/frequency detector 11 comprises a first logic circuit (not shown) for receiving a reference frequency fed from the signal input 16 and a feedback signal fed from the feedback module 15 and then generating four signals A, B, C, and D (ex. charge-up signal, inverse charge-up signal, charge-down signal, and inverse charge-down signal). The phase/frequency detector 11 further comprises a second logic circuit 113 including a first line section 111 and a second line section 112 in series with the first line section 111. The first line section 111 comprises four PMOSs (P-type metal oxide semiconductors) 114 in parallel with each other. The second line section 112 comprises four NMOSs (N-type metal oxide semiconductors) 115 in series with each other. Each of the PMOSs 114 is adapted to receive a signal from a corresponding one of the signals A, B, C, and D. Also, each of the signals A, B, C, and D is fed to a corresponding one of the NMOSs 115. Note that the second logic circuit 113 is implemented as a NAND gate and for outputting a reset signal in case of all of the signals A, B, C and D being logic high (or low). Also, construction and operation of the phase/frequency detector 11 and its equivalent are well known to those skilled in the art. For example, an artisan skilled in the art may replace the NAND gate with an OR gate and modify associated circuitry without departing from the scope of the invention. Accordingly, further description of the phase/frequency detector 11 is omitted for purposes of brevity and convenience only, and is not limiting.

The NMOSs 115 are coupled in series. Thus, it is required to sequentially detect each of the NMOSs 115 in order to determine whether any one of the NMOSs 115 is conducted or not. Hence, a logic operation about each of the received signals A, B, C, and D is not performed synchronously by the NMOSs 115. As a result, the logic level (U/D) signal generated by the phase/frequency detector 11 might be incorrect. Thus, continuing improvements in the exploitation of logic circuit capable of synchronously performing a logic operation about each of the received signals are constantly being sought in order to overcome the inadequacy of the prior art.

### SUMMARY OF THE INVENTION

After considerable research and experimentation, a logic circuit having a low signal skew according to the present invention has been devised so as to overcome the above drawback of the prior art.

It is an object of the present invention to provide a logic circuit coupled to a first voltage level and a second voltage level. The logic circuit comprises a first circuit including a plurality of first transistors coupled in parallel, each of the first transistors adapted to receive one of a plurality of input signals. The logic circuit further comprises a second circuit coupled in series with the first circuit, the second circuit including a plurality of transistor sets each including a plurality of second transistors. The number of the transistor sets is the same as that of the first transistors. The number of the first transistors is the same as that of the second transistors of each transistor set. The second transistors of each transistor set are coupled in series. Each second transistor is coupled to one of the input signals. Each transistor set receives the input signals according to a sequence different from that of each of the other transistor sets.

The above and other objects, features and advantages of the present invention will become apparent from the following detailed description taken with the accompanying drawings.

### BRIEF DESCRIPTION OF THE DRAWINGS

FIG. 1 is a block circuit diagram of a conventional PLL;

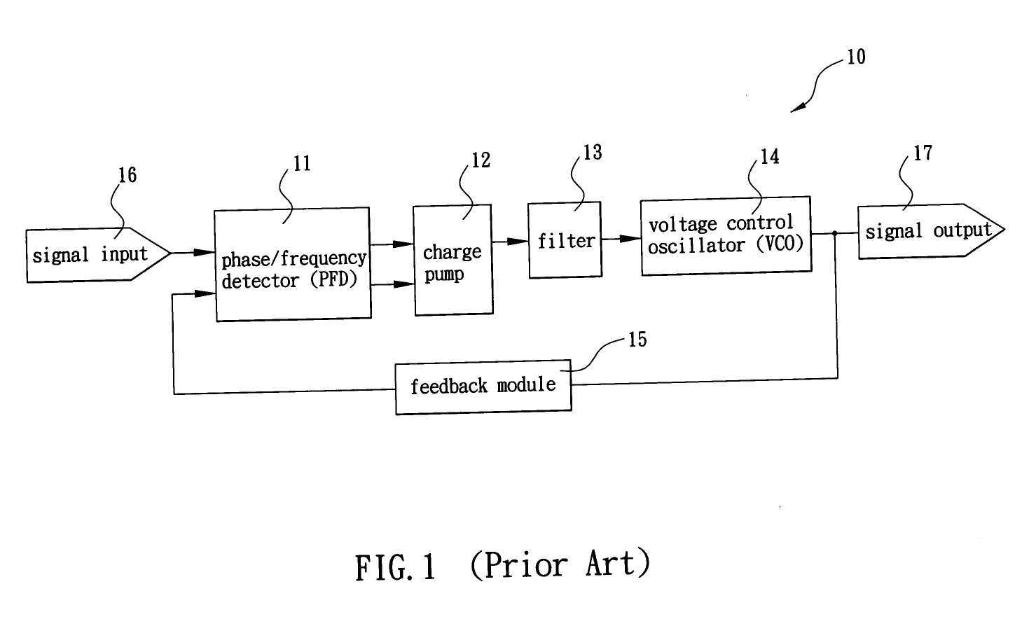

FIG. 2 is a detailed circuit diagram of the phase/frequency detector in FIG. 1;

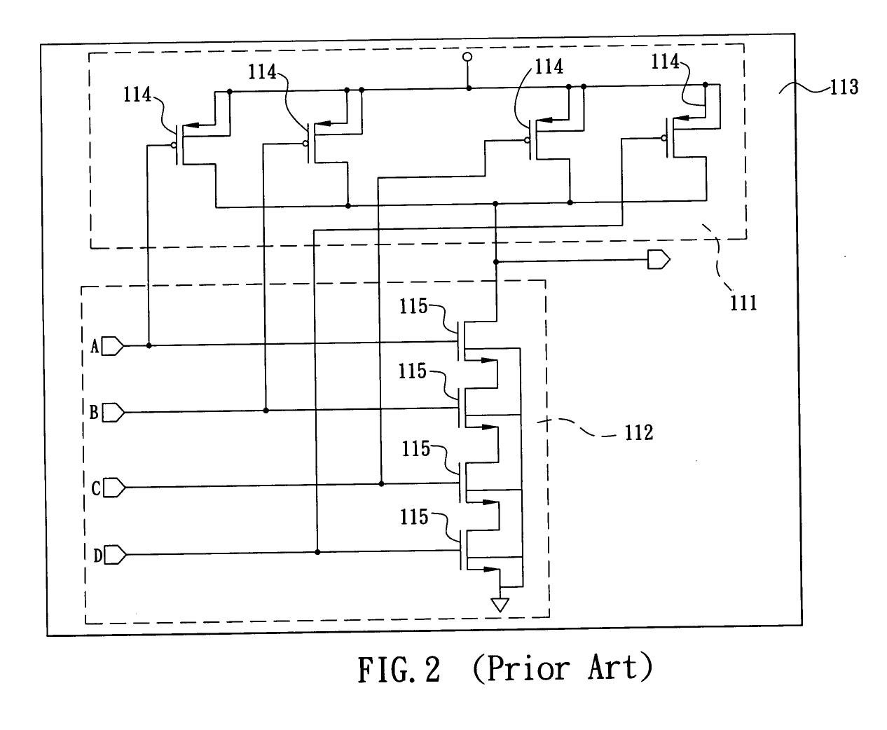

FIG. 3 is a detailed circuit diagram of a first preferred embodiment of logic circuit according to the invention; and

FIG. 4 is a detailed circuit diagram of a second preferred embodiment of logic circuit according to the invention.

### DETAILED DESCRIPTION OF THE PREFERRED EMBODIMENTS

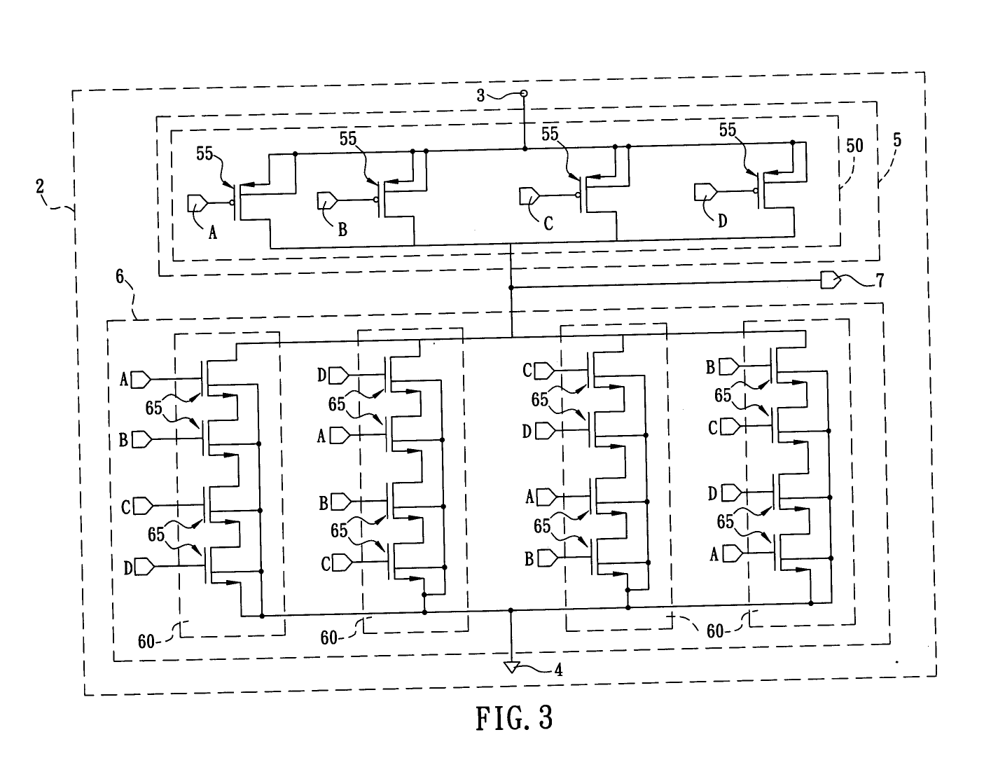

Referring to FIG. 3, a logic circuit 2 in accordance with a first preferred embodiment of the invention is shown. The logic circuit 2 is implemented as a NAND gate. The logic circuit 2 comprises a first circuit 5 and a second circuit 6 both disposed between a first voltage level 3 and a second voltage level 4. The first voltage level 3 has a level different from that of the second voltage level 4. The first circuit 5 is in series with the second circuit 6. A plurality of input signals A, B, C, and D are coupled to both the first and second circuits 5 and 6. The second circuit 6 processes each of the input signals A, B, C, and D with substantially the same time delay. Thus, the second circuit 6 may process the input signals A, B, C, and D without errors. The logic circuit 2 further comprises an output 7 provided at a line coupled to the first circuit 5 and the second circuit 6. The logic circuit 2 may turn on the first circuit 5, turn off the second circuit 6 at the same time, and cause the output 7 to output the first voltage level 3 based on the input signals A, B, C, and D. Alternatively, the logic circuit 2 may turn off the first circuit 5, turn on the second circuit 6 at the same time, and cause the output 7 to output the second voltage level 4 based on the input signals A, B, C, and D.

Referring to FIG. 3 again, in the first preferred embodiment of the invention the first circuit 5 comprises a plurality of first transistors 55 coupled in parallel. Each of the first transistors 55 is coupled to a corresponding one of the inputs A, B, C, and D. It is noted that the first circuit 5 could comprise four input units 50 with only a first input unit 50 shown in FIG. 3 for the sake of brevity. As shown in FIG. 3, the first input unit 50 comprises a plurality of first transistors 55 for respectively receiving the input signals A, B, C and D. Each of the remaining input units 50 (not shown in FIG. 3) may have the same structure as that of the first input unit 50. Besides, each of the input units 50 receives the input signals A, B, C and D in a sequence different from that of each of the other input units 50. For example, a second input unit 50 (not shown in FIG. 3) are coupled to the input signals D, A, B, and C, a third input unit 50 (not shown in FIG. 3) are coupled to the input signals C, D, A, and B, and a fourth input unit 50 (not shown in FIG. 3) are coupled to the input signals B, C, D, and A respectively.

Referring to FIG. 3 again, the second circuit 6 comprises a plurality of transistor sets 60 each having a plurality of second transistors 65. The second transistors 65 of one transistor set 60 are coupled in series. Each of the second transistors 65 of one transistor set 60 is coupled to one of the input signals A, B, C, and D. Also, the second transistors 65 of one transistor set 60 receive the input signals A, B, C, and D in a manner different from that of the second transistors 65 of each of the remaining transistor sets 60 as shown in FIG. 3. As such, to each of the input signals A, B, C, and D, the second circuit 6 operate with the same time delay. As an end, the logic circuit 2 may process the input signals A, B, C, and D synchronously.

Referring to FIG. 3 again, in the first preferred embodiment of the invention the logic circuit 2 is implemented as a NAND gate. In a second preferred embodiment of the invention, the logic circuit 2 of FIG. 3 could be implemented as an OR gate when each first transistor 55 is implemented as a NMOS (N-type metal oxide semiconductor) and each second transistor 65 is implemented as a PMOS (P-type metal oxide semiconductor).

Referring to FIG. 3 again, for further discussing characteristics of the first preferred embodiment of the invention details of embodying the logic circuit 2 in a PFD of a PLL as an exemplary example is described below. The first circuit 5 comprises four PMOSs each coupled to a corresponding one of the input signals A, B, C, and D. The second circuit 6 comprises four transistor sets 60 each having four NMOSs. Four NMOSs of the transistor set 60 are coupled to the input signals A, B, C, and D respectively. Also, the NMOSs of each transistor set 60 receive the input signals A, B, C and D according to a sequence different from that of each of the remaining transistor sets 60. Besides, the first voltage level 3 is a high voltage level and the second voltage level 4 is a low voltage level.

In view of above, the logic circuit 2 comprises the first circuit 5 including a plurality of PMOSs and the second circuit 6 including a plurality of NMOSs. The NMOSs are conducted when the input signals A, B, C and D correspond a rising pulse signal. And in turn, the second voltage level 4 is sent from each conducted NMOS to the output 7 for output. At this time, the PMOSs are cut off, thereby prohibiting the first voltage level 3 from sending to the output 7. The PMOSs will be conducted when at least one of the input signals A, B, C, and D is a lowering pulse signal. And in turn, the first voltage level 3 is sent from each conducted PMOS to the output 7 for output. At this time, the NMOSs are cut off, thereby prohibiting the second voltage level 4 from sending to the output 7.

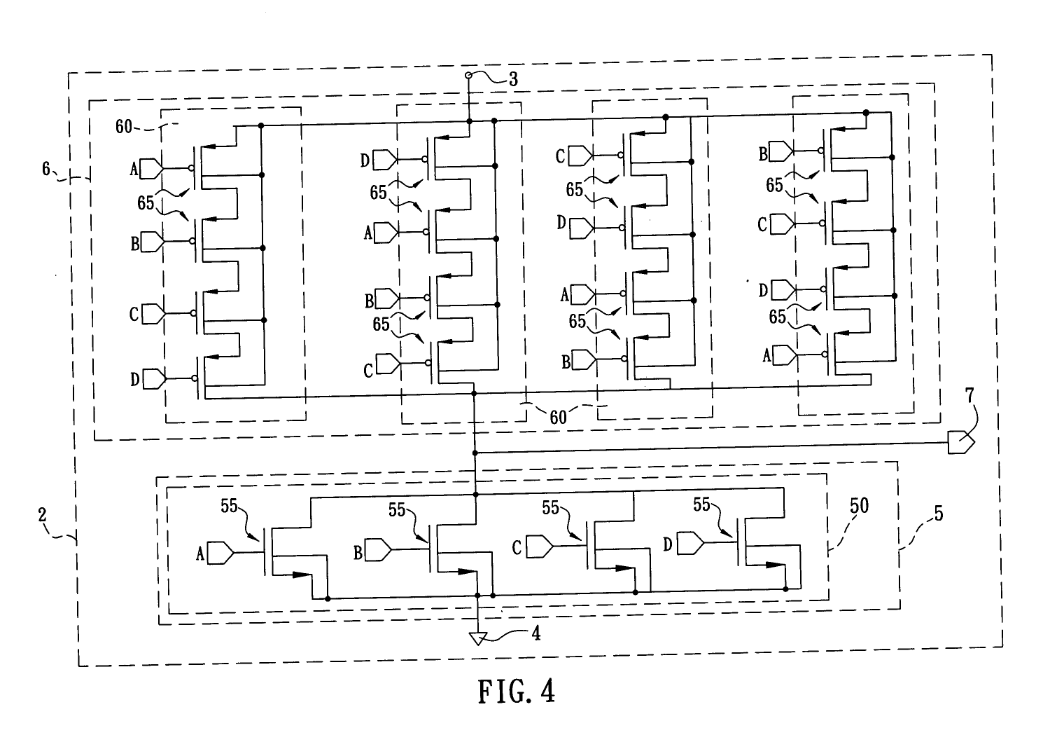

Referring to FIG. 4, in a third preferred embodiment of the invention the logic circuit 2 is implemented as a NOR gate. The first circuit 5 comprises four NMOSs each adapted to receive one of the input signals A, B, C, and D. The second circuit 6 comprises four transistor sets 60 each including four PMOSs. Each PMOS of one transistor set 60 is coupled to one of the input signals A, B, C, and D. Also, the PMOSs of each transistor set 60 receive the input signals A, B, C and D in a way different from that of each of the remaining transistor sets 60. Besides, the first voltage level 3 in this embodiment is a high voltage level such as a VDD. The second voltage level 4 in this embodiment is a low voltage level such as a GND. At this time, the PMOSs will be conducted when the input signals A, B, C, and D correspond a lowering pulse signal. And in turn, the first voltage level 3 is sent from each conducted PMOS to the output 7 for output. As a result, the NMOSs are cut off, thereby prohibiting the second voltage level 4 from sending to the output 7. Alternatively, the corresponding NMOSs are conducted when at least one of the input signals A, B, C and D corresponds a rising pulse signal. And in turn, the second voltage level 4 is sent from each conducted NMOS to the output 7 for output. At this time, the corresponding PMOSs are cut off, thereby prohibiting the first voltage level 3 from sending to the output 7.

Referring to FIG. 4 again, in the third preferred embodiment of the invention the logic circuit 2 is implemented as a NOR gate. In a fourth preferred embodiment of the invention, the logic circuit 2 of FIG. 4 could be implemented as an AND gate when each first transistor 55 is implemented as a PMOS (P-type metal oxide semiconductor) and each second transistor 65 is implemented as a NMOS (N-type metal oxide semiconductor).

Note that the preferred embodiments disclosed above is not used for limiting the implementation of the invention. It is contemplated that any logic circuit having a plurality of input signals and being capable of synchronously performing a logic operation with respect to the input signals is within the scope of the invention.

While the invention herein disclosed has been described by means of specific embodiments, numerous modifications and variations could be made thereto by those skilled in the art without departing from the scope and spirit of the invention set forth in the claims.

What is claimed is:

1. A logic circuit coupled a first voltage level and a second voltage level, comprising:
a first circuit coupled to the first voltage level comprising:
a plurality of first transistors for respectively receiving a plurality of input signals, each of the first transistors coupling to the first voltage level and outputting the first voltage level when at least one of the input signals corresponding to a first logic level;
a second circuit coupled to the second voltage level comprising:
a plurality of transistor sets coupled to the second voltage level, each of the transistor sets comprising a plurality of second transistors for respectively receiving the input signals, each of the transistor sets receiving the input signals in a sequence different from that of each of the other transistor sets, each of the transistor sets outputting the second voltage level when all of the input signals corresponding to a second logic level; and
an output terminal, coupled to the first circuit and the second circuit, for outputting the first voltage level from the first circuit or the second voltage level from the second circuit.

2. The logic circuit of claim 1, wherein the logic circuit is a NAND gate.

3. The logic circuit of claim 1, wherein the logic circuit is an OR gate.

4. The logic circuit of claim 1, wherein the logic circuit is a NOR gate.

5. The logic circuit of claim 1, wherein the logic circuit is an AND gate.

6. The logic circuit of claim 1, wherein the logic circuit is embodied in a PFD (phase/frequency detector).

7. The logic circuit of claim 1, wherein each of the first transistors is a P-type transistor or a N-type transistor, and each of the second transistors is a P-type transistor or a N-type transistor.

8. The logic circuit of claim 1, wherein the transistor sets are coupled together in parallel and the second transistors are coupled together in series.

9. The logic circuit of claim 8, wherein the first transistors are coupled together in parallel.

10. The logic circuit of claim 1, wherein the number of the transistor sets is the same as the number of the first transistors.

11. The logic circuit of claim 10, wherein the number of the second transistors of each of the transistor sets is the same as the number of the first transistors.
